(19) United States
(12) Patent Application Publication
(10) Pub. No.: US 2023/0151204 A1
(43) Pub. Date: May 18, 2023

(54) RESIN COMPOSITION, RESIN FILM MEMBER, PRINTED WIRING BOARD, AND METHOD FOR MANUFACTURING THE PRINTED WIRING BOARD

(71) Applicant: Panasonic Intellectual Property Management Co., Ltd., Osaka (JP)

(72) Inventors: Yohei MAEDA, Fukushima (JP); Eiichiro SAITO, Osaka (JP); Akihiro YAMAUCHI, Osaka (JP)

(21) Appl. No.: 17/916,487

(22) PCT Filed: Apr. 5, 2021
(86) PCT No.: PCT/JP2021/014453

§ 371 Date: Sep. 30, 2022

(30) Foreign Application Priority Data
Apr. 6, 2020 (JP) 2020-068545

(51) Int. Cl. C08L 63/00; C08K 5/5313; C08J 5/18; H05K 1/03; C08K 5/523; C08K 5/5399; C08K 3/36

(52) U.S. Cl. CPC C08L 63/00; C08K 5/5313; C08J 5/18; H05K 1/0373; C08K 5/523; C08K 5/5399; C08K 3/36; C08J 2363/00; C08L 2201/02; C08K 2003/2227

(57) ABSTRACT

A resin composition contains a resin component (A) and a phosphorus-containing flame retardant (B). The resin component (A) contains an epoxy resin (a1), of which the viscosity at 25° C. is equal to or less than 50000 mPa·s. The proportion of the epoxy resin (a1) to the resin component (A) is equal to or greater than 20% by mass. The phosphorus-containing flame retardant (B) includes a phosphorus-containing flame retardant (B1) that neither melts nor thermally decomposes at a temperature lower than 150° C.

### CROSS-REFERENCE OF RELATED APPLICATIONS

This application is the U.S. National Phase under 35 U.S.C. § 371 of International Patent Application No. PCT/JP2021/014453, filed on Apr. 5, 2021, which in turn claims the benefit of Japanese Patent Application No. 2020-068545, filed on Apr. 6, 2020, the entire disclosures of which Applications are incorporated by reference herein.

### TECHNICAL FIELD

The present disclosure generally relates to a resin composition, a resin film member, a printed wiring board, and a method for manufacturing the printed wiring board. More particularly, the present disclosure relates to a resin composition having thermosetting properties, a resin film member including a resin layer made of the resin composition, a printed wiring board made of the resin composition, and a method for manufacturing the printed wiring board using the resin film member.

### BACKGROUND ART

When a printed wiring board is manufactured, a stack is formed by stacking, for example, a core member including a conductor and a resin layer including either an uncured product or semi-cured product of a resin composition one on top of the other, and then the stack is hot-pressed. For example, Patent Literature 1 teaches manufacturing a multilayer printed wiring board by forming a stack with a thermally meltable resin film having thermosetting properties interposed between a substrate with a via hole and a prepreg containing an inorganic filler.

### CITATION LIST

### Patent Literature

Patent Literature 1: JP 2003-37362 A

### SUMMARY OF INVENTION

The problem to be overcome by the present disclosure is to provide: a resin composition that makes it easier to impart flexibility to a resin layer when a resin film member including the resin layer is formed and that reduces the chances of components in a resin layer flowing out of the resin layer when a stack including the resin layer is hot-pressed; a resin film member including a resin layer made of the resin composition; a printed wiring board made of the resin composition; and a method for manufacturing a printed wiring board using the resin film member.

A resin composition according to an aspect of the present disclosure contains a resin component (A) and a phosphorus-containing flame retardant (B). The resin component (A) contains an epoxy resin (a1), of which a viscosity at 25° C. is equal to or less than 50000 mPa·s. The proportion of the epoxy resin (a1) to the resin component (A) is equal to or greater than 20% by mass. The phosphorus-containing flame retardant (B) includes a phosphorus-containing flame retardant (B1) that neither melts nor thermally decomposes at a temperature lower than 150° C.

A resin film member according to another aspect of the present disclosure includes: a carrier film; and a resin layer stacked on the carrier film and containing an uncured product or semi-cured product of the resin composition described above.

A printed wiring board according to still another aspect of the present disclosure includes conductor wiring and an insulating layer laid on top of the conductor wiring. The insulating layer contains a cured product of the resin composition described above.

A method for manufacturing a printed wiring board according to yet another aspect of the present disclosure includes hot-pressing a stack including a core member having conductor wiring and the resin layer included in the resin film member described above.

### BRIEF DESCRIPTION OF DRAWINGS

FIG. 1 is a schematic cross-sectional view of a resin film member according to an exemplary embodiment of the present disclosure;

FIG. 2A is a schematic cross-sectional view illustrating a state where the film member according to the exemplary embodiment of the present disclosure and a core member are stacked one on top of the other;

FIG. 2B is a schematic cross-sectional view illustrating a state where a resin layer according to the exemplary embodiment of the present disclosure and the core member are stacked one on top of the other;

FIG. 3A is a schematic cross-sectional view of a stack including the resin layer according to the exemplary embodiment of the present disclosure; and

FIG. 3B is a schematic cross-sectional view of a printed wiring board according to the exemplary embodiment of the present disclosure.

### DESCRIPTION OF EMBODIMENTS

To make a resin film member for use to manufacture a printed wiring board more easily handleable, a resin layer included in the resin film member preferably has flexibility and powdering of the resin layer should be reduced as much as possible.

Thus, to increase the flexibility of the resin layer, the present inventors modified the composition of the resin layer. However, the present inventors discovered that the resin layer with the modified composition tended to exhibit excessively increased flowability when heated. Thus, when the resin layer was stacked over conductor wiring of a substrate, for example, and the stack was hot-pressed, components of the resin layer flowed out easily from the stack including the resin layer. Particularly when the resin layer is laid on top of thick conductor wiring, the resin layer needs to have sufficient flowability to fill the gaps of the conductor wiring with the resin layer. In that case, components of the resin layer will flow out particularly easily. Thus, an insulating layer formed out of such a resin layer will often have an insufficient resin content.

To overcome such a problem, the present inventors carried out research and development to obtain a resin composition that makes it easier to impart flexibility to a resin layer when a resin film member including the resin layer is formed and that reduces the chances of components in the resin layer flowing out of the resin layer when a stack including the resin layer is hot-pressed, thus conceiving the concept of the present disclosure.

An exemplary embodiment of the present disclosure will now be described.

A resin composition according to this embodiment (hereinafter also referred to as a “composition (X)”) contains a resin component (A) and a phosphorus-containing flame retardant (B). The resin component (A) contains an epoxy resin (a1), of which the viscosity at 25° C. is equal to or less than 50000 mPa·s. The proportion of the epoxy resin (a1) to the resin component (A) is equal to or greater than 20% by mass. The phosphorus-containing flame retardant (B) includes a phosphorus-containing flame retardant (B1) that neither melts nor thermally decomposes at a temperature lower than 150° C. (hereinafter referred to as a “heat-resistance flame retardant (B1)”).

According to this embodiment, the phosphorus-containing flame retardant (B) may make a cured product of the composition (X) flame-retardant, and therefore, may make the cured product flame-retardant without using any halogen compound. Thus, this may make both the composition (X) and the cured product thereof halogen-free materials. Note that the definition of the halogen-free material is compliant with the standard (JPCA-ES01) defined by Japan Electronics Packaging and Circuits Association (JPCA).

Also, the resin component (A) contains an epoxy resin (a1) and the proportion of the epoxy resin (a1) to the resin component (A) is equal to or greater than 20% by mass. This makes it easier to impart flexibility to the resin layer 1 made of the composition (X) and reduce the chances of causing powdering of the resin layer. Consequently, this increases the chances of making a resin film member 10 including the resin layer 1 easily handleable.

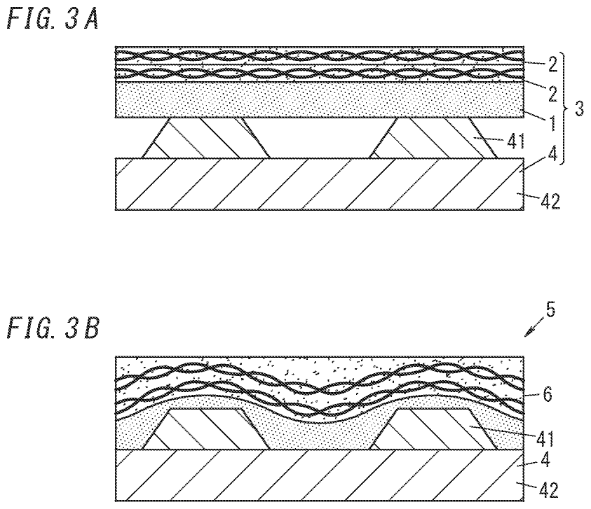

Furthermore, the composition (X) contains an epoxy resin (a1) with low viscosity but also contains the heat-resistant flame retardant (B1) that does not melt at a temperature lower than 150° C. This reduces, when a stack 3 (see FIG. 3A) including the resin layer 1 is hot-pressed, the chances of components in the resin layer 1 flowing out of the resin layer 1.

Consequently, this embodiment makes it easier to impart flexibility to a resin layer 1 when the resin layer 1 is formed out of the composition (X) and reduces the chances of components in the resin layer 1 flowing out of the resin layer 1 when a stack 3 including the resin layer 1 is hot-pressed.

The chemical makeup of the composition (X) will be described in further detail.

The composition (X) contains the resin component (A) and the phosphorus-containing flame retardant (B) as described above.

The resin component (A) is a component with thermosetting properties. The resin component (A) contains a thermosetting resin. A component included in the thermosetting resin may be a monomer or a prepolymer, whichever is appropriate. The thermosetting resin includes an epoxy resin (a). The thermosetting resin may further include, for example, at least one resin selected from the group consisting of a polyimide resin, a phenolic resin, a bismaleimide triazine resin, and a thermosetting polyphenylene ether resin.

The epoxy resin (a) contains at least one component selected from the group consisting of, for example, bisphenol A epoxy resins, bisphenol F epoxy resins, cresol-novolac epoxy resins, bisphenol A novolac epoxy resins, bisphenol F novolac epoxy resins, naphthalene epoxy resins, biphenyl epoxy resins, dicyclopentadiene epoxy resins, and polyfunctional epoxy resins.

Note that these are only exemplary components that may be contained in the thermosetting resin and exemplary components that may be contained in the epoxy resin (a) and should not be construed as limiting.

The epoxy resin (a) includes an epoxy resin (a1), of which the viscosity at 25° C. is equal to or less than 50000 mPa·s. That is to say, the resin component (A) contains the epoxy resin (a1). Note that the viscosity is measured by a Brookfield viscosimeter using a standard spindle No. 3 under the condition including the number of revolutions of 60 rpm. The viscosity of the epoxy resin (a) at 25° C. is more preferably equal to or less than 25000 mPa·s and even more preferably equal to or less than 10000 mPa·s. This particularly significantly increases the chances of making the resin film member 10 including the resin layer 1 handleable. Meanwhile, the viscosity is preferably equal to or greater than 1000 mPa·s. This makes it easier to increase, when the composition (X) contains an inorganic filler, the degree of dispersion of the inorganic filler and also makes it easier to control the thickness of the resin layer 1 when the resin layer 1 is formed out of the composition (X). The viscosity is more preferably equal to or greater than 3000 mPa·s and even more preferably equal to or greater than 5000 mPa·s.

The epoxy resin (a1) may include an appropriate liquid epoxy resin that satisfies the viscosity condition described above. For example, the epoxy resin (a1) may include at least one component selected from the group consisting of, for example, liquid bisphenol A epoxy resins, liquid bisphenol F epoxy resins, liquid bisphenol B epoxy resins, and liquid bisphenol E epoxy resins, all of which satisfy the viscosity condition described above. The epoxy resin (a1) including such a liquid epoxy resin makes it easier to effectively increase the flexibility of the resin layer 1 made of the composition (X) and reduce the chances of causing powdering of the resin layer 1. Note that these are only exemplary components included in the epoxy resin (a1) and should not be construed as limiting.

The proportion of the epoxy resin (a1) to the resin component (A) is equal to or greater than 20% by mass. This would likely allow the epoxy resin (a1) to effectively increase the flexibility of the resin layer 1 and reduce the chances of causing powdering of the resin layer 1. The proportion of the epoxy resin (a1) is preferably equal to or less than 50% by mass and even more preferably equal to or less than 40% by mass. Meanwhile, the proportion of the epoxy resin (a1) is preferably equal to or greater than 25% by mass and even more preferably equal to or greater than 30% by mass. The epoxy resin (a) may consist of only the epoxy resin (a1). Alternatively, the epoxy resin (a) may include additional epoxy resins other than the epoxy resin (a1). In the latter case, the proportion of the epoxy resin (a1) to the epoxy resin (a) in its entirety may be, for example, equal to or less than 50% by mass.

The epoxy resin (a) may include not only the epoxy resin (a1) but also an epoxy resin (a2) which is solid at 25° C. That is to say, the resin component (A) may further contain the epoxy resin (a2). This makes it easier to mold the composition (X) into a film shape by applying the composition (X), for example, thus making it easier to form the resin layer 1 out of the composition (X). The epoxy resin (a2) may contain at least one component selected from the group consisting of, for example, polyfunctional epoxy resins such as an epoxy resin with a naphthalene skeleton and a novolac epoxy resin. Note that these are only exemplary components included in the epoxy resin (a2) and should not be construed as limiting. The proportion of the epoxy resin (a2) to the epoxy resin (a) in its entirety is preferably equal to or greater than 40% by mass. This makes it particularly easier for the epoxy resin (a2) to increase the heat resistance of the cured product. The proportion of the epoxy resin (a2) is preferably equal to or less than 80% by mass. This makes it easier to effectively increase the flexibility of the cured product and significantly reduce the chances of causing powdering of the resin layer 1. The proportion of the epoxy resin (a2) is more preferably equal to or greater than 50% by mass and even more preferably equal to or greater than 60% by mass.

As described above, the composition (X) contains the phosphorus-containing flame retardant (B), and the phosphorus-containing flame retardant (B) includes the heat-resistant flame retardant (B1) that neither melts nor thermally decomposes at a temperature lower than 150° C. As used herein, the phrase “neither melts nor thermally decomposes at a temperature lower than 150° C.” means that if the heat-resistant flame retardant (B1) has a melting point, the melting point is equal to or higher than 150° C. and that if the heat-resistant flame retardant (B1) does not have a melting point (i.e., if the heat-resistant flame retardant (B1) thermally decomposes without melting when heated in a solid state), the thermal decomposition temperature thereof is equal to or higher than 150° C.

The heat-resistant flame retardant (B1) contains at least one component selected from the group consisting of, for example, EXOLIT OP935 (with a thermal decomposition temperature equal to or higher than 300° C.), EXOLIT OP930, EXOLIT OP1230, EXOLIT OP1240, EXOLIT OP1312, and EXOLIT OP1400, all of which are metal salts of phosphinic acid manufactured by Clariant Chemicals Ltd. Note that these are only exemplary components included in the heat-resistant flame retardant (B1) and should not be construed as limiting.

The proportion of the heat-resistant flame retardant (B1) to the resin component (A) is preferably equal to or greater than 3% by mass and equal to or less than 10% by mass. Making this proportion equal to or greater than 3% by mass allows the phosphorus-containing flame retardant (B) to significantly reduce the chances of components in the resin layer 1 flowing out of the resin layer 1. Making this proportion equal to or less than 10% by mass makes it easier to fill, particularly when the resin layer 1 is molded while causing to flow over the conductor wiring 41, the gaps of the conductor wiring 41 with the resin layer 1. This proportion is more preferably equal to or greater than 4% by mass and equal to or less than 6% by mass and is even more preferably equal to or greater than 5% by mass and equal to or less than 6% by mass.

The proportion of the heat-resistant flame retardant (B1) to the phosphorus-containing flame retardant (B) is preferably equal to or greater than 30% by mass. This allows the heat-resistant flame retardant (B1) to particularly significantly reduce the chances of the components in the resin layer 1 flowing out of the resin layer 1. This proportion is more preferably equal to or greater than 50% by mass and even more preferably equal to or greater than 60% by mass. Optionally, the phosphorus-containing flame retardant (B) may consist of only the heat-resistant flame retardant (B1).

The phosphorus-containing flame retardant (B) may include a component other than the heat-resistant flame retardant (B1), namely, a phosphorus-containing flame retardant (B2), of which the melting point is lower than 150° C. (hereinafter referred to as a “non-heat-resistant flame retardant (B2)”). The non-heat-resistant flame retardant (B2) contains at least one component selected from the group consisting of, for example, PX-200 (with a melting point 90° C.), which is an aromatic condensed phosphate ester manufactured by Daihachi Chemical Industry Co., Ltd., Rabitle FP-100 (with a melting point of 110° C.), which is a phosphazene compound manufactured by Fushimi Pharmaceutical Co., Ltd., and CR733S which is an aromatic condensed phosphate ester manufactured by Daihachi Chemical Industry Co., Ltd. Note that these are only exemplary components included in the non-heat-resistant flame retardant (B2) and should not be construed as limiting.

Optionally, the resin component (A) may further contain at least one of a curing agent (b) or a curing accelerator (c). This enables further reducing the outflow of components in the resin layer 1 by improving the curing properties of the composition (X).

The curing agent (b) contains at least one component selected from the group consisting of, for example, amine-based curing agents, bifunctional or higher-functional phenolic curing agents, acid anhydride-based curing agents, dicyandiamide, and low-molecular-weight polyphenylene ether compounds. The components included in the curing agent (b) are not limited to these as long as the components may react with the epoxy resin (a) to cause the composition (X) to be cured. The content of the curing agent (b) is preferably equal to or greater than 0.3 equivalents and equal to or less than 1.5 equivalents, more preferably equal to or greater than 0.4 equivalents and equal to or less than 1.2 equivalents, and even more preferably equal to or greater than 0.45 equivalents and equal to or less than 1.1 equivalents, with respect to 1 equivalent of the epoxy resin (a).

The curing accelerator (c) contains at least one component selected from the group consisting of, for example, imidazole compounds, tertiary amine compounds, organic phosphine compounds, and metal soaps. The components included in the curing accelerator (c) are not limited to these as long as the components accelerate the curing reaction of the resin component (A). The content of the curing accelerator (c) with respect to the epoxy resin (a) is preferably equal to or greater than 0.02% by mass and equal to or less than 2.0% by mass, more preferably equal to or greater than 0.05% by mass and equal to or less than 1.0% by mass, and even more preferably equal to or greater than 0.07% by mass and equal to or less than 0.7% by mass.

The composition (X) may further contain an inorganic filler. The inorganic filler may control the coefficient of linear expansion of a cured product of the composition (X) and may also improve the heat resistance and flame resistance of the composition (X). The inorganic filler contains at least one material selected from the group consisting of, for example, silica, aluminum hydroxide, magnesium hydroxide, aluminum silicate, magnesium silicate, talc, clay, mica, and molybdenum compounds.

The proportion of the inorganic filler to the composition (X) is preferably equal to or greater than 60% by mass and equal to or less than 90% by mass. Making this proportion equal to or greater than 60% by mass enables improving the heat resistance and flame resistance of the cured product of the composition (X) particularly significantly. Also, making this proportion equal to or less than 90% by mass increases the chances of the composition (X) having good moldability. This proportion is more preferably equal to or greater than 75% by mass and equal to or less than 85% by mass.

Optionally, the composition (X) may contain a solvent to adjust its viscosity, for example. The solvent contains, for example, at least one of an appropriate organic solvent or water. The organic solvent contains at least one component selected from the group consisting of, for example, benzene, toluene, N,N-dimethylformamide (DMF), acetone, methyl ethyl ketone, methanol, ethanol, and cellosolves.

Optionally, the composition (X) may further contain additives other than these components. The additives may contain at least one component selected from the group consisting of, for example, coupling agents, antifoaming agents, heat stabilizers, antistatic agents, UV absorbers, dyes, pigments, lubricants, and dispersants. Note that these are only exemplary components included in the additives and should not be construed as limiting.

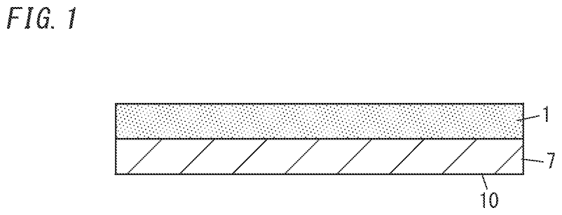

As shown in FIG. 1, the resin film member 10 according to this embodiment includes: a carrier film 7; and a resin layer 1 stacked on the carrier film and containing an uncured product or semi-cured product of the composition (X). The resin layer 1 may be used as material for making a printed wiring board 5. That is to say, a printed wiring board 5 including an insulating layer 6 that contains a cured product of the resin layer 1 (i.e., a cured product of the composition (X)) may be formed by using the resin layer 1.

The carrier film 7 is a resin film with flexibility such as a film made of polyethylene terephthalate. A surface, on which the resin layer 1 is to be laid, of the carrier film 7 is preferably subjected to treatment that increases the mold release ability thereof. Examples of such treatment that increases the mold release ability include silicone coating. The carrier film 7 may have a thickness equal to or greater than 10 μm and equal to or less than 150 μm, for example.

To manufacture the resin film member 10, the composition (X) is formed into a sheet shape on the carrier film 7 by application method, for example, and then heated to be either dried or semi-cured. In this manner, a resin layer 1 is formed out of either an uncured product or semi-cured product of the composition (X) and a resin film member 10 including the carrier film 7 and the resin layer 1 is obtained. The heating temperature may be, for example, equal to or higher than 100° C. and equal to or lower than 160° C. and the heating duration may be, for example, equal to or longer than 5 minutes and equal to or shorter than 10 minutes.

The resin layer 1 preferably has a thickness equal to or greater than 50 μm and equal to or less than 400 μm. This makes it easier to fill, particularly when the resin layer 1 is molded while causing to flow over the conductor wiring 41, the gaps of the conductor wiring 41 with the resin layer 1. The resin layer 1 more preferably has a thickness equal to or greater than 55 μm and equal to or less than 300 μm, and even more preferably has a thickness equal to or greater than 60 μm and equal to or less than 250 μm.

Also, the total thickness of the resin film member 10, i.e., the combined thickness of the carrier film 7 and the resin layer 1, may be, for example, equal to or greater than 60 μm and equal to or less than 550 μm. Making this thickness equal to or greater than 60 μm makes it particularly easy for the carrier film 7 to support the resin layer 1 and reduces the chances of the resin layer 1 being torn while the resin film member 10 is handled. Making this thickness equal to or less than 550 μm makes it particularly easy to peel the resin layer 1 off the carrier film 7 and may reduce the chances of the resin layer 1 cracking while the resin film member 10 is stored in a roll. This thickness is more preferably equal to or greater than 65 μm and even more preferably equal to or greater than 70 μm. Also, this thickness is more preferably equal to or less than 450 μm and even more preferably equal to or less than 400 μm.

The resin layer 1 preferably has a melt viscosity equal to or greater than 400 Pa·s at 150° C. This significantly reduces the chances of the components in the resin layer 1 flowing out of the stack 3 while the stack 3 including the resin layer 1 is hot-pressed. This melt viscosity is more preferably equal to or greater than 450 Pa·s and even more preferably equal to or greater than 500 Pa·s. It is preferable that the melt viscosity be equal to or less than 10000 Pa·s. This makes it easier for the resin layer 1 to be deformed, if the resin layer 1 is laid on top of the conductor wiring 41 while the stack 3 including the resin layer 1 is hot-pressed, to follow the conductor wiring 41, thus reducing the chances of leaving unfilled gaps in the insulating layer 6 formed out of the resin layer 1. This melt viscosity is more preferably equal to or less than 8000 Pa·s and even more preferably equal to or less than 6000 Pa·s. The melt viscosity of the resin layer 1 is controllable by, for example, appropriately adjusting the types and contents of components respectively included in the epoxy resin (a1) and heat-resistant flame retardant (B1) in the composition (X). A method for measuring the melt viscosity will be described later with respect to specific examples.

A printed wiring board 5 may be manufactured by using the resin film member 10 according to this embodiment. The printed wiring board 5 may include, for example, conductor wiring 41 and an insulating layer 6 laid on top of the conductor wiring 41. The insulating layer 6 includes a cured product of the composition (X). The printed wiring board 5 may be manufactured by hot-pressing a stack 3 including, for example, the resin layer 1 and a core member 4 having the conductor wiring 41. A specific exemplary method for manufacturing the printed wiring board 5 will be described below.

A resin film member 10, a prepreg 2, and a core member 4 are provided.

Details of the resin film member 10 are as already described above.

The prepreg 2 includes, for example, a base member and an uncured product or semi-cured product of a thermosetting resin composition (hereinafter referred to as a “composition (Y)”) impregnated into the base member. The prepreg 2 may be formed by, for example, impregnating the composition (Y) into the base member and then heating the composition (Y) to dry or semi-cure the composition (Y).

The base member is, for example, either woven fabric or non-woven fabric. The base material may be made of, for example, glass fiber, an inorganic fiber other than glass fiber, or an organic fiber. The organic fiber includes at least one material selected from the group consisting of, for example, an aramid fiber, a poly(paraphenylene benzobisoxazole) (PBO) fiber, a poly(benzoimidazole) (PBI) fiber, a poly(tetrafluoroethylene) (PTFE) fiber, a poly(paraphenylene benzobisthiazole) (PBZT) fiber, and a fully aromatic polyester fiber.

The composition (Y) contains a thermosetting resin and may contain, as needed, a component selected from the group consisting of, for example, curing agents, curing accelerators, rubber components, inorganic fillers, flame retardants, and organic solvents.

The thermosetting resin contains at least one component selected from the group consisting of, for example, epoxy resins, polyimide resins, phenolic resins, and bismaleimide triazine resins. The epoxy resin may contain at least one component selected from the group consisting of, for example, oxazolidone epoxy resins, bisphenol A epoxy resins, bisphenol F epoxy resins, bisphenol S epoxy resins, biphenyl epoxy resins, alicyclic epoxy resins, diglycidyl ether compounds of a polyfunctional phenol, diglycidyl ether compounds of a polyfunctional alcohol, phenol novolac epoxy resins, each of which is a glycidyl ether compound of a polycondensate of a phenol and formaldehyde, cresol novolac epoxy resins, and bisphenol A novolac epoxy resins.

The curing agent may contain at least one component selected from the group consisting of, for example, diamine-based curing agents, bifunctional or higher-functional phenolic curing agents, acid anhydride-based curing agents, dicyandiamide, and low-molecular-weight polyphenylene ether compounds.

The curing accelerator may contain at least one component selected from the group consisting of, for example, imidazole compounds, tertiary amine compounds, organic phosphine compounds, and metal soaps.

The rubber component contains, for example, elastomer particles having a core-shell structure.

The inorganic filler contains, for example, at least one material selected from the group consisting of, for example, silica, molybdenum compounds, aluminum hydroxide, magnesium hydroxide, aluminum silicate, magnesium silicate, talc, clay, and mica.

The flame retardant preferably contains a non-halogen flame retardant. The non-halogen flame retardant contains, for example, a phosphorus-containing compound or a nitrogen-containing compound.

The organic solvent may contain at least one component selected from the group consisting of, for example, benzene, toluene, N, N-dimethylformamide (DMF), acetone, methyl ethyl ketone, methanol, ethanol, and cellosolves.

The core member 4 includes, for example, an insulating layer 42 and conductor wiring 41 laid on top of the insulating layer 42. The insulating layer 42 may be made of, for example, a resin with electrical insulation properties. The conductor wiring 41 may be made of a metal such as copper. The thickness of the conductor wiring 41 is not limited to any particular value. In this embodiment, the resin layer 1 fills the gaps of the conductor wiring 41 so easily as described above that good fillability is achieved even if the conductor wiring 41 is rather thick. Thus, the printed wiring board 5 according to this embodiment is easily applicable as a board for industrial equipment, on-board equipment, and other pieces of equipment which are required to cause a relatively large amount of electric current to flow therethrough. The conductor wiring 41 may have a thickness equal to or greater than 200 μm, for example. Also, to achieve good fillability, the conductor wiring 41 preferably has a thickness equal to or less than 1000 μm. The thickness of the conductor wiring 41 is more preferably equal to or greater than 200 μm and equal to or less than 800 μm, and even more preferably equal to or greater than 200 μm and equal to or less than 600 μm.

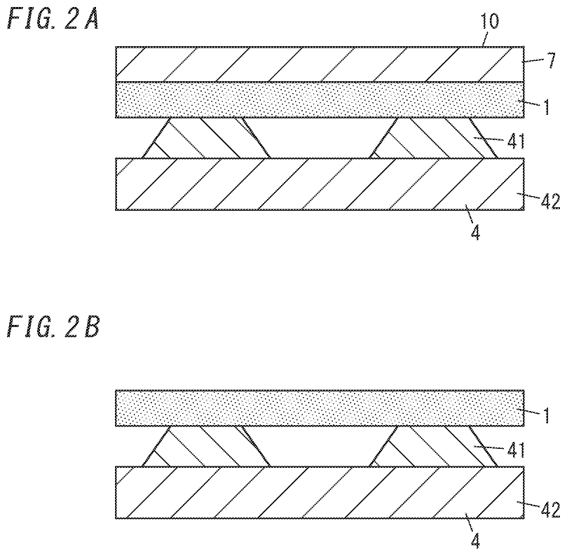

To manufacture the printed wiring board 5, the resin film member 10 is stacked on the core member 4 as shown in FIG. 2A, for example, such that the resin layer and the conductor wiring 41 face each other. Subsequently, with the resin layer 1 kept stacked on the core member 4, the carrier film 7 is removed from the resin layer 1 as shown in FIG. 2B. Then, a single or a plurality of prepregs 2 are further stacked on the resin layer 1. That is to say, the core member 4, the resin layer 1, and the single or plurality of prepregs 2 are stacked one on top of another in this order. Optionally, a sheet of metal foil such as copper foil may be further laid on top of the prepreg(s) 2. In this manner, a stack 3 including the prepreg(s) 2, the resin layer 1, and the core member 4 is obtained as shown in FIG. 3A.

This stack 3 is hot-pressed. The condition for hot pressing may be set as appropriate according to the respective compositions and dimensions of the resin layer 1 and the prepregs 2. For example, the heating temperature may be equal to or higher than 170° C. and equal to or lower than 210° C., the press pressure may be equal to or greater than 0.5 MPa and equal to or less than 3.0 MPa, and the duration may be equal to or longer than 60 minutes and equal to or shorter than 120 minutes.

Hot-pressing the stack 3 in this manner causes the resin layer 1 and the prepregs 2 to be melted and then cured, thereby forming an insulating layer 6 as a cured product of the resin layer 1 and the prepregs 2. At this time, the prepregs 2 including the base member are not directly in contact with the conductor wiring 41 but the resin layer 1 not including the base member is in contact with the conductor wiring 41, thus making it easier for the resin layer 1 to fill the gaps of the conductor wiring 41 without flowing. This reduces the chances of leaving unfilled gaps between the insulating layer 6 and the conductor wiring 41. In addition, this also reduces the chances of components in the resin layer 1 flowing out of the resin layer 1 during the hot pressing. This makes it easier to form the insulating layer 6 as designed even if the conductor wiring 41 is rather thick.

As a result, a printed wiring board 5, which includes an insulating layer 42 derived from the core member 4, the conductor wiring 41 derived from the core member 4, and the insulating layer 6 formed out of the resin layer 1 and the prepregs 2 and in which the insulating layer 42, the conductor wiring 41, and the insulating layer 6 are stacked one on top of another in this order, is obtained as shown in FIG. 3B.

Note that the printed wiring board 5 formed out of the resin layer 1 does not have to have the configuration described above. For example, in the foregoing description, the printed wiring board 5 includes the insulating layer 6 as a cured product of the resin layer 1 and the prepregs 2. However, this is only an example and should not be construed as limiting. Alternatively, the insulating layer 6 may also be formed out of only the resin layer 1. In other words, the printed wiring board 5 may include an insulating layer 6 as a cured product of the resin layer 1. Still alternatively, the printed wiring board 5 may also include a plurality of (e.g., three or more) insulating layers. In that case, at least one of the plurality of insulating layers may include a cured product of the resin layer 1 (i.e., a cured product of the composition (X)).

### EXAMPLES

Next, more specific examples of this embodiment will be described. Note that the examples to be described below are only examples of this embodiment and should not be construed as limiting.

(1) Preparation of Composition

A composition was prepared by mixing together respective components shown in the “chemical makeup” column of Table 1. The following are the details of those components:
Liquid bisphenol A epoxy resin manufactured by DIC Corporation, product number EPICLON 850-S, having a viscosity at 25° C. of 14000 mPa·s and an equivalent of 190;
Liquid bisphenol F epoxy resin manufactured by DIC Corporation, product number EPICLON 830-S, having a viscosity at 25° C. of 3500 mPa·s and an equivalent of 170;
Solid epoxy resin manufactured by DIC Corporation, product number EPICLON HP-4710, having an equivalent of 170;
DICY: dicyandiamide, having an equivalent of 21;
Zinc octanoate;
Silica manufactured by Admatechs, product number SO-25R;
Aluminum hydroxide: manufactured by Kawai Lime Industry Co., Ltd., product number ALH-F;
OP935: metal salt of phosphinic acid, manufactured by Clariant Chemicals Ltd., product name EXOLIT OP935, having a thermal decomposition temperature equal to or higher than 300° C.;
OP930: metal salt of phosphinic acid, manufactured by Clariant Chemicals Ltd., product name EXOLIT OP930, having a thermal decomposition temperature equal to or higher than 300° C.;
OP1230: metal salt of phosphinic acid, manufactured by Clariant Chemicals Ltd., product name EXOLIT OP1230, having a thermal decomposition temperature equal to or higher than
OP1312: metal salt of phosphinic acid, manufactured by Clariant Chemicals Ltd., product name EXOLIT OP1312, having a thermal decomposition temperature equal to or higher than 300° C.;
PX-200: phosphate ester compound, manufactured by Daihachi Chemical Industry Co., Ltd., product number PX-200, having a melting point of 90° C.; and
FP-100: phosphazene compound, manufactured by Fushimi Pharmaceutical Co., Ltd., product name Rabitle FP-100, having a melting point of 110° C.

(2) Formation of Resin Film Member

A silicon coated film manufactured by Mitsui Chemicals Tohcello Inc. (product number SP-PET having a thickness of 74 μm) was used as a carrier film. The composition was applied onto the carrier film and then heated at 80° C. for 1.5 minutes. Subsequently, the composition was heated at 100° C. for 1.5 minutes and then heated at 150° C. for 1.5 minutes. In this manner, a resin layer having a thickness of 200 μm and a volatile content of 0.8% by mass was formed. As a result, a resin film member including a carrier film and a resin layer supported by the carrier layer was obtained. Note that in the third comparative example, the resin layer cracked right after having been heated and could not be subjected to evaluation.

(3) Manufacturing of Printed Wiring Board

A core member, including an insulating layer having a thickness of 200 μm and conductor wiring having a thickness of 400 μm and laid on top of the insulating layer, was provided. The conductor wiring had a line width of 800 μm, a space width of 1000 μm, and a residual copper ratio of 50%.

Also, as a prepreg, R-1551(S) manufactured by Panasonic Corporation (including an epoxy resin as its resin component and glass cloth as its base member (Glass Cloth Style 2116)) was provided.

A resin layer included in the resin film member was laid on top of the conductor wiring on the core member and then two prepregs were further stacked thereon to obtain a stack. This stack was hot-pressed. The heating temperature was set as follows during the hot-pressing process. First, the temperature was increased at a temperature increase rate of 2° C./min from 30° C. to 200° C. and then maintained at 200° C. for 120 minutes. The press pressure was set at 0.5 MPa for the first 60 minutes and then set at 2.0 MPa for the next 145 minutes. In this manner, a printed wiring board, including an insulating layer and conductor wiring derived from the core member and an insulating layer formed out of a resin layer and prepregs, was obtained.

(4) Evaluation

(4-1) Melt viscosity at 150° C.

The melt viscosity at 150° C. of the resin layer was measured using a viscoelasticity measuring instrument (Soliquid meter manufactured by UBM Co., Ltd, product number Rheosol-G3000).

To make the measurement, a sample having a diameter of 10 mm and a thickness of 3 mm was formed by compressing the resin layer. As pre-measurement treatment, the sample was disposed on a plate with a diameter of 31 mm, heated to 80° C. at a temperature increase rate of 190° C./min with a load of 1000 g applied to the sample, and then rapidly cooled to a temperature equal to or lower than 30° C., thereby adhering the sample to the plate. Subsequently, the melt viscosity at 150° C. of the sample was measured under the condition including a load of 1000 g, a frequency of 10 Hz, and an angular velocity of 0.5 rad/sec.

(4-2) Flame Resistance

The flame resistance of the insulating layer formed out of the resin layer and the prepregs was evaluated by flammability test compliant with the UL94 standard.

(4-3) Outflow Performance

A cross section of the printed wiring board was observed to confirm the thickness of a cured product of the resin layer that was laid on top of the conductor wiring. The resin layer that turned out to have a thickness equal to or greater than 20 μm was graded “A.” Otherwise, the resin layer was graded “C.”

(4-4) R-10 bending evaluation

The resin film member was wound around a circular column with a diameter of 10 mm. The resin film member, of which the resin layer did not crack as a result, was graded “A.” The resin film member, of which the resin layer cracked as a result, was graded “C.”

(4-5) Powdering Evaluation

The resin film member was cut off with a box cutter. The resin film member that produced a significant amount of powder due to fragmentation around the cross section was graded “C.” The resin film member that produced only a small amount of powder was graded “B.” The resin film member that caused no fragmentation around the cross section and produced no powder was graded “A.”

(4-6) Fillability

A cross section of the printed wiring board was observed to see if there were any voids in the insulating layer formed out of the resin layer and the prepregs. The printed wiring board in which no voids were recognized was graded “A.” The printed wiring board in which some voids were recognized was graded “C.”

TABLE 1

| | | | | | | Cmp. Examples | | | Examples | | |
|---|---|---|---|---|---|---|---|---|---|---|---|
| | | | | | | 1 | 2 | 3 | 1 | 2 | 3 |
| Chemical | Epoxy resin | A | a | a1 | Liquid | 35 | 35 | 15 | 25 | 35 | 35 |
| makeup | | | | | bisphenol A | | | | | | |
| (parts | | | | | epoxy resin | | | | | | |
| by | | | | | (viscosity | | | | | | |
| mass) | | | | | 14000 mPa · s, | | | | | | |
| | | | | | equivalent 190) | | | | | | |
| | | | | | Liquid | 0 | 0 | 0 | 0 | 0 | 0 |
| | | | | | bisphenol F | | | | | | |
| | | | | | epoxy resin | | | | | | |
| | | | | | (viscosity 3500 | | | | | | |
| | | | | | mPa · s, | | | | | | |
| | | | | | equivalent 170) | | | | | | |
| | | | | a2 | Solid epoxy | 60.9 | 60.9 | 80.9 | 70.9 | 60.9 | 60.9 |
| | | | | | resin | | | | | | |
| | | | | | (equivalent 170) | | | | | | |

| Curing agent | | b | DICY | 5.7 | 5.7 | 5.8 | 5.8 | 5.7 | 5.7 |
|---|---|---|---|---|---|---|---|---|---|
| | | | (equivalent 21) | | | | | | |
| Curing accelerator | | c | Zinc octanoate | 0.5 | 0.5 | 0.5 | 0.5 | 0.5 | 0.5 |
| Inorganic filler | | | Silica | 240 | 320 | 240 | 240 | 240 | 240 |
| | | | Aluminum | 60 | 80 | 160 | 60 | 60 | 60 |
| | | | hydroxide | | | | | | |
| Phosphorus-containing | B | B1 | OP 935 (B1) | 0 | 0 | 5 | 5 | 5 | 5 |
| flame retardant | | | (thermal | | | | | | |
| | | | decomposition | | | | | | |
| | | | temperature ≥ | | | | | | |
| | | | 300° C.) | | | | | | |
| | | | OP 930 (B1) | 0 | 0 | 0 | 0 | 0 | 0 |
| | | | (thermal | | | | | | |
| | | | decomposition | | | | | | |
| | | | temperature ≥ | | | | | | |
| | | | 300° C.) | | | | | | |
| | | | OP 1230 (B1) | 0 | 0 | 0 | 0 | 0 | 0 |
| | | | (thermal | | | | | | |
| | | | decomposition | | | | | | |
| | | | temperature ≥ | | | | | | |
| | | | 300° C.) | | | | | | |
| | | | OP 1312 (B1) | 0 | 0 | 0 | 0 | 0 | 0 |
| | | | (thermal | | | | | | |
| | | | decomposition | | | | | | |
| | | | temperature ≥ | | | | | | |
| | | | 300° C.) | | | | | | |
| | | B2 | PX-200 | 7 | 7 | 0 | 0 | 0 | 0 |
| | | | (melting point | | | | | | |
| | | | 90° C.) | | | | | | |
| | | | FP-100 (melting | 13 | 13 | 10 | 10 | 10 | 5 |
| | | | point 110° C.) | | | | | | |

| Component | Proportion of epoxy resin (a1) to resin component (A) | | 34.3 | 34.3 | 14.7 | 24.5 | 34.3 | 34.3 |
|---|---|---|---|---|---|---|---|---|
| content | | | | | | | | |
| (% by | | | | | | | | |
| mass) | Proportion of epoxy resin (a1) to entire epoxy resin (a) | | 36.5 | 36.5 | 15.6 | 26.1 | 36.5 | 36.5 |
| | Proportion of epoxy resin (a2) to entire epoxy resin (a) | | 63.5 | 63.5 | 84.4 | 73.9 | 63.5 | 63.5 |
| | Proportion of phosphorus-containing flame retardant | | 0.0 | 0.0 | 4.9 | 4.9 | 4.9 | 4.9 |
| | (B1) to resin component (A) | | | | | | | |
| | Proportion of phosphorus-containing flame retardant | | 0.0 | 0.0 | 33.3 | 33.3 | 33.3 | 50.0 |
| | (B1) to phosphorus-containing flame retardant (B) | | | | | | | |
| | Proportion of phosphorus-containing flame retardant | | 100.0 | 100.0 | 66.7 | 66.7 | 66.7 | 50.0 |
| | (B2) to phosphorus-containing flame retardant (B) | | | | | | | |
| | Equivalent ratio of curing agent (b) to epoxy resin (a) | | 0.5 | 0.5 | 0.5 | 0.5 | 0.5 | 0.5 |
| | Proportion of curing accelerator (c) to epoxy resin (a) | | 0.5 | 0.5 | 0.5 | 0.5 | 0.5 | 0.5 |
| | Proportion of inorganic filler to composition (X) | | 71.1 | 76.6 | 77.3 | 71.9 | 71.9 | 72.8 |
| Evaluation | Melt viscosity (Pa · s) at 150° C. | | 260 | 420 | — | 600 | 590 | 700 |
| | Flame resistance | | V-0 | V-0 | — | V-0 | V-0 | V-0 |
| | | | grade | grade | | grade | grade | grade |
| | Outflow performance | Thickness (μm) | 10 | 15 | — | 40 | 30 | 50 |
| | | of cured product | | | | | | |
| | | of film member | | | | | | |
| | | on conductor | | | | | | |
| | | wiring | | | | | | |
| | | Grade | C | C | — | A | A | A |

| | | | | | | |
|---|---|---|---|---|---|---|
| R-10 bending evaluation | A | A | C | A | A | A |
| Powdering evaluation | A | A | C | A | A | A |
| Fillability (with or without voids) | A | A | — | A | A | A |

TABLE 2

| | | | | | | Examples | | | | | |
|---|---|---|---|---|---|---|---|---|---|---|---|
| | | | | | | 4 | 5 | 6 | 7 | 8 | 9 |
| Chemical | Epoxy resin | A | a | a1 | Liquid | 35 | 35 | 0 | 25 | 25 | 25 |
| makeup | | | | | bisphenol A | | | | | | |
| (parts | | | | | epoxy resin | | | | | | |
| by | | | | | (viscosity | | | | | | |
| mass) | | | | | 14000 mPa · s, | | | | | | |
| | | | | | equivalent | | | | | | |
| | | | | | 190) | | | | | | |
| | | | | | Liquid | 0 | 0 | 25 | 0 | 0 | 0 |
| | | | | | bisphenol F | | | | | | |
| | | | | | epoxy resin | | | | | | |
| | | | | | (viscosity 3500 | | | | | | |
| | | | | | mPa · s, | | | | | | |
| | | | | | equivalent | | | | | | |
| | | | | | 170) | | | | | | |
| | | | | a2 | Solid epoxy | 60.9 | 60.9 | 70.9 | 70.9 | 70.9 | 70.9 |
| | | | | | resin | | | | | | |
| | | | | | (equivalent | | | | | | |
| | | | | | 170) | | | | | | |

| Curing agent | | b | DICY | 5.7 | 5.7 | 5.9 | 5.8 | 5.8 | 5.8 |
|---|---|---|---|---|---|---|---|---|---|
| | | | (equivalent 21) | | | | | | |
| Curing accelerator | | c | Zinc octanoate | 0.5 | 0.5 | 0.5 | 0.5 | 0.5 | 0.5 |
| Inorganic filler | | | Silica | 240 | 320 | 240 | 240 | 240 | 240 |
| | | | Aluminum | 60 | 80 | 60 | 60 | 60 | 60 |
| | | | hydroxide | | | | | | |
| Phosphorus-containing | B | B1 | OP 935 (B1) | 8 | 8 | 5 | 0 | 0 | 0 |
| flame retardant | | | (thermal | | | | | | |
| | | | decomposition | | | | | | |
| | | | temperature ≥ | | | | | | |
| | | | 300° C.) | | | | | | |
| | | | OP 930 (B1) | 0 | 0 | 0 | 5 | 0 | 0 |
| | | | (thermal | | | | | | |
| | | | decomposition | | | | | | |
| | | | temperature ≥ | | | | | | |
| | | | 300° C.) | | | | | | |
| | | | OP 1230 (B1) | 0 | 0 | 0 | 0 | 5 | 0 |
| | | | (thermal | | | | | | |
| | | | decomposition | | | | | | |
| | | | temperature ≥ | | | | | | |
| | | | 300° C.) | | | | | | |
| | | | OP 1312 (B1) | 0 | 0 | 0 | 0 | 0 | 6 |
| | | | (thermal | | | | | | |
| | | | decomposition | | | | | | |
| | | | temperature ≥ | | | | | | |
| | | | 300° C.) | | | | | | |
| | | B2 | PX-200 | 0 | 0 | 0 | 0 | 0 | 0 |
| | | | (melting point | | | | | | |
| | | | 90° C.) | | | | | | |
| | | | FP-100 | 0 | 0 | 10 | 10 | 10 | 10 |
| | | | (melting point | | | | | | |
| | | | 110° C.) | | | | | | |

| Component | Proportion of epoxy resin (a1) to resin component (A) | | 34.3 | 34.3 | 24.4 | 24.5 | 24.5 | 24.5 |
|---|---|---|---|---|---|---|---|---|
| content | | | | | | | | |
| (% by | | | | | | | | |
| mass) | Proportion of epoxy resin (a1) to entire epoxy resin (a) | | 36.5 | 36.5 | 26.1 | 26.1 | 26.1 | 26.1 |
| | Proportion of epoxy resin (a2) to entire epoxy resin (a) | | 63.5 | 63.5 | 73.9 | 73.9 | 73.9 | 73.9 |
| | Proportion of phosphorus-containing flame retardant | | 7.8 | 7.8 | 4.9 | 4.9 | 4.9 | 5.9 |
| | (B1) to resin component (A) | | | | | | | |
| | Proportion of phosphorus-containing flame retardant | | 100.0 | 100.0 | 33.3 | 33.3 | 33.3 | 37.5 |
| | (B1) to phosphorus-containing flame retardant (B) | | | | | | | |
| | Proportion of phosphorus-containing flame retardant | | 0.0 | 0.0 | 66.7 | 66.7 | 66.7 | 62.5 |
| | (B2) to phosphorus-containing flame retardant (B) | | | | | | | |
| | Equivalent ratio of curing agent (b) to epoxy resin (a) | | 0.5 | 0.5 | 0.5 | 0.5 | 0.5 | 0.5 |
| | Proportion of curing accelerator (c) to epoxy resin (a) | | 0.5 | 0.5 | 0.5 | 0.5 | 0.5 | 0.5 |
| | Proportion of inorganic filler to composition (X) | | 73.2 | 78.4 | 71.9 | 71.9 | 71.9 | 71.7 |
| Evaluation | Melt viscosity (Pa · s) at 150° C. | | 1000 | 7500 | 600 | 550 | 500 | 500 |
| | Flame resistance | | V-0 | V-0 | V-0 | V-0 | V-0 | V-0 |
| | | | grade | grade | grade | grade | grade | grade |
| | Outflow performance | Thickness | 120 | 160 | 40 | 35 | 30 | 30 |
| | | (μm) of cured | | | | | | |
| | | product of film | | | | | | |
| | | member on | | | | | | |
| | | conductor | | | | | | |
| | | wiring | | | | | | |
| | | Grade | A | A | A | A | A | A |

| | | | | | | |
|---|---|---|---|---|---|---|
| R-10 bending evaluation | A | A | A | A | A | A |
| Powdering evaluation | A | A | B | A | A | A |
| Fillability (with or without voids) | A | C | A | A | A | A |

### REFERENCE SIGNS LIST

1 Resin Layer
10 Resin Film Member
3 Stack
6 Insulating Layer
4 Core Member
41 Conductor Wiring
42 Insulating Layer
5 Printed Wiring Board
7 Carrier Film

1. A resin composition containing a resin component (A) and a phosphorus-containing flame retardant (B),
the resin component (A) containing an epoxy resin (a1), of which a viscosity at 25° C. is equal to or less than 50000 mPa·s, proportion of the epoxy resin (a1) to the resin component (A) being equal to or greater than 20% by mass,
the phosphorus-containing flame retardant (B) including a phosphorus-containing flame retardant (B1) that neither melts nor thermally decomposes at a temperature lower than 150° C.

2. The resin composition of claim 1, wherein
the resin component (A) further contains at least one of a curing agent (b) or a curing accelerator (c).

3. The resin composition of claim 1, wherein
proportion of the phosphorus-containing flame retardant (B1) to the resin component (A) is equal to or greater than 3% by mass and equal to or less than 10% by mass.

4. The resin composition of claim 1, wherein
proportion of the phosphorus-containing flame retardant (B1) to the phosphorus-containing flame retardant (B) is equal to or greater than 30% by mass.

5. The resin composition of claim 1, wherein
proportion of the phosphorus-containing flame retardant (B) to the resin composition in its entirety is equal to or greater than 1% by mass and equal to or less than 5% by mass.

6. The resin composition of claim 1, further containing an inorganic filler.

7. The resin composition of claim 6, wherein
proportion of the inorganic filler to the resin composition in its entirety is equal to or greater than 60% by mass and equal to or less than 90% by mass.

8. The resin composition of claim 1, wherein
the resin component (A) further contains an epoxy resin (a2) in a solid state at 25° C.

9. A resin film member comprising:
a carrier film; and
a resin layer stacked on the carrier film and containing an uncured product or semi-cured product of the resin composition of claim 1.

10. The resin film member of claim 9, wherein
the resin layer has a thickness equal to or greater than 50 μm and equal to or less than 400 μM.

11. The resin film member of claim 9, wherein
the resin layer has a melt viscosity equal to or greater than 400 Pa·s at 150° C.

12. A printed wiring board comprising: conductor wiring; and an insulating layer laid on top of the conductor wiring,
the insulating layer containing a cured product of the resin composition of claim 1.

13. A method for manufacturing a printed wiring board, the method comprising hot-pressing a stack including: a core member having conductor wiring; and the resin layer included in the resin film member of claim 9.

14. The resin composition of claim 2, further containing an inorganic filler.

15. The resin composition of claim 2, wherein
the resin component (A) further contains an epoxy resin (a2) in a solid state at 25° C.

16. The resin composition of claim 14, wherein
the resin component (A) further contains an epoxy resin (a2) in a solid state at 25° C.
